(19) United States
(12) Patent Application Publication
(10) Pub. No.: US 2006/0151885 A1
(43) Pub. Date: Jul. 13, 2006

(54) Semiconductor device and method of manufacturing the same

(76) Inventor: Dong-Yeal Keum, Seoul (KR)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/302,473

(22) Filed: Dec. 14, 2005

(30) Foreign Application Priority Data
Dec. 15, 2004 (KR) 10-2004-0106148

(51) Int. Cl. H01L 21/44; H01L 23/48

(52) U.S. Cl. 257/774; 438/672; 257/E23.011

(57) ABSTRACT

A method of manufacturing a semiconductor device consistent with embodiments of the present invention includes forming a first insulation layer on a semiconductor substrate provided with an isolation layer and an active region; exposing a part of the active region by patterning the first insulation layer; forming a second insulation layer on the patterned first insulation layer; forming a contact hole exposing the active region and the edge portion of the first insulation layer by patterning the second insulation layer; and forming a metal layer on the second insulation layer and the exposed active region. Consequently, a junction leakage current that may be generated at the interface between the active region and the isolation layer in forming the metal contact hole can be suppressed, so the yield and reliability of devices may be enhanced.

### CROSS-REFERENCE TO RELATED APPLICATION

This application claims priority to and the benefit of Korean Patent Application No. 10-2004-0106148 filed in the Korean Intellectual Property Office on Dec. 15, 2004, the entire contents of which are incorporated herein by reference.

### BACKGROUND OF THE INVENTION

(a) Field of the Invention

The present invention relates to a semiconductor device and a method of manufacturing the same.

(b) Description of the Related Art

Recently, as design rules of a semiconductor device have been decreased, the size of an active region has also been decreased. However, because the size of a metal contact hole relates directly to the contact characteristics, it is problematic to reduce the contact size because the overlap margin for a metal contact hole over the active region also decreases. If the metal contact hole is larger than the active region to ensure the overlap between the metal contact hole and the active region, the interface between the active region and a neighboring isolation layer (i.e., a shallow trench isolation region) may be damaged in an etching process for forming the metal contact hole. As a result, junction leakage current of the device increases, and the reliability of the device is deteriorated.

Thus, a method of forming a metal contact that can reduce device failure due to misalignment with the active region without reducing the size of the metal contact hole is required.

It is to be understood that the above information is only for enhancement of understanding of the background of the invention and does not necessarily constitute prior art.

### SUMMARY OF THE INVENTION

The present invention has been made in an effort to provide a semiconductor device and a method of manufacturing the same having advantages of improved reliability by preventing junction leakage current at an interface between an active region and an isolation layer.

An exemplary method of manufacturing a semiconductor device according to an embodiment of the present invention includes forming a first insulation layer on a semiconductor substrate provided with an isolation layer and an active region; exposing a part of the active region by patterning the first insulation layer; forming a second insulation layer on the patterned first insulation layer; forming a contact hole exposing the active region and the edge portion of the first insulation layer by patterning the second insulation layer; and forming a metal layer on the second insulation layer and the exposed active region.

In a further embodiment, the process of forming a metal layer may include forming a barrier metal layer on the second insulation layer and exposed active region, forming a metal plug in the contact hole, and forming a metal line.

In addition, an opening of the patterned first insulation layer may be formed on the active region.

In a further embodiment, a size of the contact hole may be equal to or larger than that of the active region.

In a further embodiment, the first insulation layer may be formed as a silicon nitride layer, and the second insulation layer may be formed as a silicon oxide layer. The silicon nitride layer may have a thickness of 100-500 Å.

In a further embodiment, a silicide layer may be formed between the active region and the metal layer.

In a further embodiment, a photomask for patterning the first insulation layer may be a reverse-phase type of photomask for patterning the active region, and a pattern of the photomask for patterning the first insulation layer may be larger than a pattern of the photomask for patterning the active region.

In addition, a developed pattern of the first insulation layer using the photomask may be larger than a developed pattern of the active region by 10 to 20 nm.

An exemplary semiconductor device according to another embodiment of the present invention includes a semiconductor substrate provided with an isolation layer and an active region; a first insulation layer pattern formed on the semiconductor substrate and exposing a part of the active region; a second insulation layer pattern formed on the first insulation layer pattern and having a contact hole pattern exposing the active region and the edge-portion of the first insulation layer pattern; and a metal layer formed on the second insulation layer pattern and the exposed active region.

In a further embodiment, the metal layer may include a barrier metal layer on the second insulation layer pattern and exposed active region, a metal plug in the contact hole, and a metal line on the barrier metal layer and metal plug.

In a further embodiment, an opening of the first insulation layer pattern may be formed on the active region.

In addition, a size of the contact hole may be equal to or larger than that of the active region.

In a further embodiment, a silicide layer may be formed between the active region and the metal layer.

In a further embodiment, the first insulation layer may be a silicon nitride layer, and the second insulation layer may be a silicon oxide layer. The thickness of the silicon nitride layer may be 100-500 Å.

### BRIEF DESCRIPTION OF THE DRAWINGS

The accompanying drawings, which are incorporated in and constitute a part of this specification, illustrate embodiments of the invention and, together with the description, serve to explain the features, advantages, and principles of the invention.

In the drawings,

FIG. 1 is a cross-sectional view of a semiconductor device according to an embodiment of the present invention.

FIG. 2 to FIG. 4 are cross-sectional views illustrating a method for forming a semiconductor device according to an embodiment of the present invention.

### DETAILED DESCRIPTION OF THE EMBODIMENTS

Embodiments of the present invention will hereinafter be described in detail with reference to the accompanying drawings. As those skilled in the art would realize, the described embodiments may be modified in various different ways, all without departing from the spirit or scope of the present invention.

To clarify multiple layers and regions, the thicknesses of the layers are enlarged in the drawings. The same reference numbers will be used throughout the drawings to refer to the same or like parts. When it is said that any part, such as a layer, film, area, or plate is positioned on another part, the part is directly on the other part or above the other part with at least one intermediate part. On the other hand, if any part is said to be positioned directly on another part, there is no intermediate part between the two parts.

Now, an exemplary semiconductor device and method of manufacturing the same according to an embodiment of the present invention will hereinafter be described in detail with reference to the accompanying drawings.

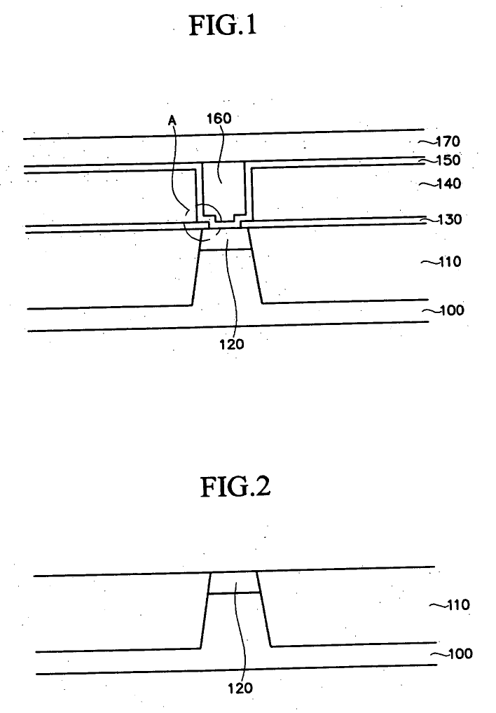

FIG. 1 is a cross-sectional view of a semiconductor device according to an embodiment of the present invention.

As shown in FIG. 1, in a semiconductor device consistent with an embodiment of the present invention, an isolation layer 110 and an active region 120 are formed on a semiconductor substrate 100.

A plurality of isolation layers 110 define a plurality of active regions 120. N+ ions or P+ ions may be implanted in active region 120.

On the semiconductor substrate 100, a first insulation layer pattern 130 is formed to expose a middle portion of active region 120 and cover an edge portion of active region 120. First insulation layer pattern 130 may be a silicon nitride layer acting as an etch stop layer for a subsequent etching process for forming a contact hole. The thickness of first insulation layer pattern 130 may be 100-500 Å. An opening of first insulation layer pattern 130 is formed on active region 120.

A second insulation layer pattern 140 is formed on first insulation layer pattern 130, and has a contact hole 141 as shown in FIG. 4. Contact hole 141 exposes active region 120 and the edge portion of first insulation layer pattern 130. Second insulation layer pattern 140 may be a silicon oxide layer for planarizing. The size of contact hole 141 may be equal to or larger than that of active region 120.

Although the size of contact hole 141 may be equal to or larger than that of active region 120, the interface A between active region 120 and isolation layer 110 is covered with first insulation layer pattern 130, and is protected in the subsequent etching process, for forming contact hole 141.

A barrier metal layer 150 may be formed on second insulation layer pattern 140 and exposed active region 120, and a metal plug 160 is formed in contact hole 141. A metal layer 170 is formed on barrier metal layer 150 and metal plug 160, so that metal plug 160 connects active region 120 to metal layer 170.

In addition, in order to reduce the contact resistance between metal plug 160 and active region 120, a silicide layer (not shown) may be formed between active region 120 and metal plug 160.

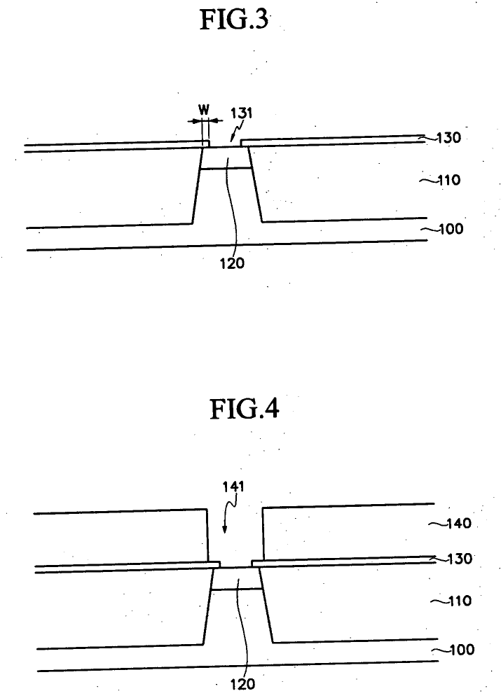

FIG. 2 to FIG. 4 are cross-sectional views showing principal stages of a semiconductor device according to an embodiment of the present invention.

As shown in FIG. 2, a plurality of isolation layers 110 are formed on a semiconductor substrate 100.

For example, a pad oxide layer and a pad nitride layer (not shown) are sequentially formed on semiconductor substrate 100, and a predetermined portion of the pad oxide layer and the pad nitride layer are etched to open a field region. By an etching process using the patterned pad nitride layer as an etching mask, semiconductor substrate 100 is etched to a predetermined depth so as to form a trench. An oxide layer or nitride layer is deposited to fill the trench, and is polished by CMP. When the pad nitride layer and pad oxide layer are removed, isolation layers 110 are formed.

Subsequently, N+ ion implantation or P+ ion implantation is performed so as to form an active region between isolation layers 110.

In addition, in order to reduce the contact resistance between a metal plug 160 and active region 120, a silicide layer (not shown) may be formed on active region 120.

Subsequently, as shown in FIG. 3, a first insulation layer 130 that is formed as a silicon nitride layer is formed on semiconductor substrate 100 provided with isolation layer 110. The silicon nitride layer will be used as an etch-stop layer in a subsequent etching process for forming a contact hole, and may have a thickness of 100-500 Å.

First insulation layer 130 is patterned so as to form an opening 131 that exposes a part of active region 120. In more detail, most of first insulation layer pattern 130 is formed on isolation layer 110, and the edge portion of first insulation layer pattern 130 is formed on the edge portion of active region 120. The overlap between the edge portion of first insulation layer pattern 130 and the edge portion of active region 120 has a predetermined width w. The overlap width w may be 10 to 20 nm.

A photomask (not shown) for patterning first insulation layer 130 may be a reverse-phase type of the photomask for patterning active region 120, and a pattern developed by the photomask for patterning first insulation layer 130 may be larger than a pattern developed by the photomask for patterning the active region by 10 to 20 nm.

Subsequently, as shown in FIG. 4, a second insulation layer 140 comprising silicon oxide is formed on first insulation layer pattern 130 to planarize the upper surface of the substrate wafer. By using a photolithography and etching process, a contact hole 141 is formed in second insulation layer 140 and exposes active region 120 and the edge portion of first insulation layer 130.

The size of contact hole 141 may be equal to or larger than that of active region 120. Although the size of contact hole 141 may be equal to or larger than that of active region 120, the interface A between active region 120 and isolation layer 110 is covered with first insulation layer pattern 130, and is protected in the subsequent etching process for forming contact hole 141. Therefore, in the etching process for forming contact hole 141, a junction leakage current that may be generated at the interface between, active region 120 and isolation layer 110 can be suppressed, so the reliability of the device may be enhanced.

Subsequently, as shown in FIG. 1, a barrier metal layer 150 is formed on second insulation layer pattern 140 and exposed active region 120, and a tungsten plug 160 is formed in contact hole 141. In addition, a metal layer 170 is formed on barrier metal layer 150 and metal plug 160.

In a semiconductor device and a method of manufacturing the same consistent with the present invention, a covering layer is formed on the interface between the isolation layer and the active region. Consequently, a junction leakage current that may be generated at the interface between the active region and the isolation layer in forming the metal contact hole can be suppressed, so the yield and reliability of devices may be enhanced.

In addition, exposure of and damage to the interface between the isolation layer and the active region due to misalignment in forming the metal contact hole can be prevented, so the yield and reliability of devices may be enhanced.

It will be apparent to those skilled in the art that various modifications and variations can be made in the disclosed process without departing from the scope or spirit of the invention. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method of manufacturing a semiconductor device, comprising:
forming a first insulation layer on a semiconductor substrate provided with an isolation layer and an active region;
exposing a part of the active region by patterning the first insulation layer;
forming a second insulation layer on the patterned first insulation layer;
forming a contact hole exposing the active region and the edge portion of the first insulation layer by patterning the second insulation layer; and
forming a metal layer on the second insulation layer and the exposed active region.

2. The method of claim 1, wherein an opening of the patterned first insulation layer is formed on the active region.

3. The method of claim 1, wherein a size of the contact hole is equal to or larger than that of the active region.

4. The method of claim 1, wherein the first insulation layer is formed as a silicon nitride layer.

5. The method of claim 4, wherein the silicon nitride layer is formed to have a thickness of 100-500 Å.

6. The method of claim 1, wherein the second insulation layer is formed as a silicon oxide layer.

7. The method of claim 1, wherein a silicide layer is formed between the active region and the metal layer.

8. The method of claim 1, wherein a photomask for patterning the first insulation layer is a reverse-phase type of a photomask for patterning the active region, and a pattern of the photomask for patterning the first insulation layer is larger than a pattern of the photomask for patterning the active region.

9. The method of claim 8, wherein a developed pattern of the first insulation layer is larger than a developed pattern of the active region by 10 to 20 nm.

10. The method of claim 1, wherein the process of forming a metal layer comprises:
forming a barrier metal layer on the second insulation layer and exposed active region;
forming a metal plug in the contact hole; and.
forming a metal line.

11. A semiconductor device, comprising:
a semiconductor substrate provided with an isolation layer and an active region;
a first insulation layer pattern formed on the semiconductor substrate and exposing a part of the active region;
a second insulation layer pattern formed on the first insulation layer pattern and having a contact hole pattern exposing the active region and the edge portion of the first insulation layer pattern; and
a metal layer formed on the second insulation layer pattern and the exposed active region.

12. The semiconductor device of claim 11, wherein an opening of the first insulation layer pattern is formed on the active region.

13. The semiconductor device of claim 11, wherein a size of the contact hole is equal to or larger than that of the active region.

14. The semiconductor device of claim 11, wherein a silicide layer is formed between the active region and the metal layer.

15. The semiconductor device of claim 11, wherein the first insulation layer is a silicon nitride layer.

16. The semiconductor device of claim 15, wherein a thickness of the silicon nitride layer is 100-500 Å.

17. The semiconductor device of claim 11, wherein the second insulation layer is a silicon oxide layer.

18. The semiconductor device of claim 11, wherein the metal layer comprises:
a barrier metal layer formed on the second insulation layer pattern and the exposed active region;
a metal plug formed in the contact hole; and
a metal line formed on the barrier metal layer and metal plug.
